(19) United States
(12) Patent Application Publication
(10) Pub. No.: US 2019/0200451 A1
(43) Pub. Date: Jun. 27, 2019

(54) ANGLE MOUNT MM-WAVE SEMICONDUCTOR PACKAGE

(71) Applicants: SASHA OSTER, Chandler, UM (US); Georgios Dogiamis, Chandler, AZ (US); TELESPHOR KAMGAING, Chandler, AZ (US); Adel Elsherbini, Chandler, AZ (US); Shawna Liff, Scottsdale, AZ (US); Aleksandar Aleksov, Chandler, AZ (US); JOHANNA SWAN, Scottsdale, AZ (US)

(72) Inventors: SASHA OSTER, Chandler, UM (US); Georgios Dogiamis, Chandler, AZ (US); TELESPHOR KAMGAING, Chandler, AZ (US); Adel Elsherbini, Chandler, AZ (US); Shawna Liff, Scottsdale, AZ (US); Aleksandar Aleksov, Chandler, AZ (US); JOHANNA SWAN, Scottsdale, AZ (US)

(73) Assignee: Intel Corporation, Santa Clara, CA (US)

(21) Appl. No.: 16/328,532

(22) PCT Filed: Sep. 29, 2016
(86) PCT No.: PCT/US16/54417

§ 371 Date: Feb. 26, 2019

(51) Int. Cl. H05K 1/02; H01L 23/66; H01L 25/065; H01L 25/11; H05K 3/36; H01L 25/16; H05K 1/14

(52) U.S. Cl. CPC H05K 1/0243; H01L 23/66; H01L 25/0655; H05K 2201/10545; H05K 3/366; H01L 25/165; H05K 1/141; H01L 25/117

(57) ABSTRACT

A millimeter wave (mm-wave) communication interface includes a first semiconductor package coupled to a first substrate and a second semiconductor package coupled to a second substrate. The second substrate may be coupled at approximately a 90° angle to the first substrate. The second semiconductor package may include a mm-wave die that modulates digital data on a high frequency microwave signal and a mm-wave launcher that launches the modulated high-frequency microwave signal into a waveguide member operably coupled to the second substrate. In such an implementation, the waveguide member may beneficially exit the second substrate along a longitudinal axis parallel to the principal plane of the first substrate. Advantageously, all high-frequency components are close coupled to the second substrate without the use of an intervening interface.

### TECHNICAL FIELD

The present disclosure relates to systems and methods for coupling waveguides to semiconductor packages.

### BACKGROUND

As more devices become interconnected and users consume more data, the demand placed on servers accessed by users has grown commensurately and shows no signs of letting up in the near future. Among others, these demands include increased data transfer rates, switching architectures that require longer interconnects, and extremely cost and power competitive solutions.

There are many interconnects within server and high performance computing (HPC) architectures today. These interconnects include within blade interconnects, within rack interconnects, and rack-to-rack or rack-to-switch interconnects. In today's architectures, short interconnects (for example, within rack interconnects and some rack-to-rack) interconnects are achieved with electrical cables—such as Ethernet cables, co-axial cables, or twin-axial cables, depending on the required data rate. For longer distances, optical solutions are employed due to the very long reach and high bandwidth enabled by fiber optic solutions. However, as new architectures emerge, such as 100 Gigabit Ethernet, traditional electrical connections are becoming increasingly expensive and power hungry to support the required data rates. For example, to extend the reach of a cable or the given bandwidth on a cable, higher quality cables may need to be used or advanced equalization, modulation, and/or data correction techniques employed which add power and latency to the system. For some distances and data rates required in proposed architectures, there is no viable electrical solution today. Optical transmission over fiber is capable of supporting the required data rates and distances, but at a severe power and cost penalty, especially for short to medium distances, such as a few meters.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1 provides a cross-sectional elevation of an illustrative millimeter wave (mm-wave) communication interface that includes a first subsystem that includes a first semiconductor package disposed on a first substrate operably and communicably coupled to a second subsystem that includes a second semiconductor package that includes at least one mm-wave die and at least one mm-wave launcher disposed on a second substrate, in accordance with at least one embodiment described herein;

FIG. 2 provides a partial cross-sectional elevation of an illustrative mm-wave communication interface system that includes a first subsystem that includes a central processing unit (CPU) die and a serializer/deserializer (SERDES) die disposed on a first substrate operably and communicably coupled to a second subsystem that includes at least one mm-wave die and at least one mm-wave launcher, in accordance with at least one embodiment described herein;

FIG. 3A provides a partial cross-sectional elevation of an illustrative mm-wave communication interface system that includes a first subsystem that includes a first substrate operably and communicably coupled to a flexible substrate disposed in a first position that includes at least one mm-wave die and at least one mm-wave launcher, in accordance with at least one embodiment described herein;

FIG. 3B provides a partial cross-sectional elevation of an illustrative mm-wave communication interface system in which the flexible second substrate has been displaced or rotated to a configuration in which at least a portion of the second substrate extends normal to the first surface of the first substrate, in accordance with at least one embodiment described herein;

FIG. 4 provides a perspective view of an illustrative mm-wave communication interface system that includes an example first substrate incorporating an edge connector suitable for physically, operably, and conductively coupling a second substrate to the first substrate, in accordance with at least one embodiment described herein;

FIG. 5 provides a perspective view of an illustrative mm-wave communication interface system that includes an example first substrate incorporating a plurality of sockets and a second substrate incorporating a corresponding plurality of pins insertable into to the plurality of sockets to provide a “press-fit” coupling between the first substrate and the second substrate, in accordance with at least one embodiment described herein;

FIG. 6 provides a perspective view of an illustrative mm-wave communication interface system that includes an example first substrate incorporating a plurality of lands and a second substrate that includes a socket having a corresponding plurality of contacts to provide a physical, operable, and communicable coupling between the first substrate and the second substrate, in accordance with at least one embodiment described herein; and

FIG. 7 provides a high-level flow diagram of an illustrative mm-wave communication interface method, in accordance with at least one embodiment described herein.

Although the following Detailed Description will proceed with reference being made to illustrative embodiments, many alternatives, modifications and variations thereof will be apparent to those skilled in the art.

### DETAILED DESCRIPTION

As data transfer speeds continue to increase, cost efficient and power competitive solutions are needed for communication between chassis and/or blades installed in a rack and between nearby racks. Such distances typically range from less than 1 meter to about 10 meters. The systems and methods disclosed herein use millimeter-wave transceivers paired with waveguides to communicate data between blades and/or racks at transfer rates in excess of 25 gigabits per second (Gbps). The millimeter wave waveguide launchers used to transfer data may be formed and/or positioned in, on, or about the semiconductor package. A significant challenge exists in aligning the millimeter-wave waveguide launcher with the waveguide member to maximize the energy transfer from the millimeter-wave waveguide launcher to the waveguide member. Further difficulties may arise when one realizes the wide variety of available waveguide members. Metallic and metal coated waveguide members are prevalent, such waveguide members may include rectangular, circular, polygonal, oval, and other shapes. Such waveguide members may include hollow members, members having a conductive and/or non-conductive internal structure, and hollow members partially or completely filled with a dielectric medium. Furthermore, space requirements of modern, rack-based, server systems often preclude “high-rise” 90° waveguide transitions from the semiconductor package to a waveguide raceway positioned along the side or rear of the rack-mounted server. In addition, waveguides may have a limited bend radius, the systems and methods described herein beneficially do not require a waveguide to bend through an angle of up to 90°. Also, the use of a curved transition may place the waveguide outside the perimeter of substrate mounted heat sinks, beneficially mitigating the impact of heat on the waveguide.

A principal goal in effecting cost-effective and efficient RF communication between semiconductor packages is coupling a waveguide to a semiconductor package such that the energy transfer between the emitter and the waveguide member is maximized. The systems and methods described herein provide new, novel, and innovative systems and methods for providing a cost-effective, highly energy efficient solution for coupling waveguides to semiconductor packages on rack mounted devices.

A typical server application involves the high speed transfer of data from a first blade mounted in a rack to a second blade mounted in the same rack or to a blade mounted in a nearby rack. As described further herein data generated at the first blade may be modulated onto a high frequency signal (e.g., a millimeter wave or microwave signal operating at a frequency of from about 30 GHz to about 300 GHz) and wirelessly communicated to the second blade. Typically, data is serialized and modulated onto the high frequency carrier signal by a mm-wave die. The mm-wave die and the mm-wave launcher may be included in a second semiconductor package that is disposed on a second substrate operably and communicably coupled at an angle of about 90° to the blade chassis. Mounting the mm-wave die and the mm-wave launcher in a position normal to the server chassis beneficially permits the operable coupling of the waveguide to the mm-wave launcher without requiring the use of bends or an adapter to route the waveguide member in a direction away from the semiconductor package.

A semiconductor package waveguide coupling system is provided. The system may include: a means for disposing a first semiconductor package on a first substrate that includes a first surface and a transversely opposed second surface; a means for disposing a second semiconductor package including at least one communicably coupled mm-wave die on a second substrate, the second substrate including a first surface and a transversely opposed second surface; a means for disposing at least one mm-wave launcher on the second substrate, the at least one mm-wave launcher communicably coupled to the mm-wave die; a means for disposing at least one waveguide member connection feature on the second substrate, the at least one waveguide member connection feature to accommodate the operable and conductive coupling of a waveguide member to the second semiconductor package proximate the at least one mm-wave launcher; a means for communicably coupling the first semiconductor package to the second semiconductor package; and a means for operably coupling the second substrate to the first substrate.

A semiconductor package waveguide coupling method is provided. The method may include disposing a first semiconductor package on a first substrate that includes a first surface and a transversely opposed second surface; disposing a second semiconductor package including at least one communicably coupled mm-wave die on a second substrate, the second substrate including a first surface and a transversely opposed second surface; disposing at least one mm-wave launcher on the second substrate, the at least one mm-wave launcher communicably coupled to the mm-wave die; disposing at least one waveguide member connection feature on the second substrate, the at least one waveguide member connection feature to accommodate the operable and conductive coupling of a waveguide member to the second semiconductor package proximate the at least one mm-wave launcher; communicably coupling the first semiconductor package to the second semiconductor package; and operably coupling the second substrate to the first substrate.

A semiconductor package waveguide coupling system is provided. The system may include: a first semiconductor package disposed on a first substrate that includes a first surface and a transversely opposed second surface; and a second semiconductor package disposed on a second substrate that includes a first surface and a transversely opposed second surface. The second semiconductor package may be communicably coupled to the first semiconductor package; and the second substrate may be operably coupled to the first substrate. The second semiconductor package may include: at least one mm-wave die communicably coupled to the second substrate; at least one mm-wave launcher communicably coupled to the mm-wave die; and at least one waveguide member connection feature to accommodate the operable and conductive coupling of a waveguide member to the second semiconductor package proximate the at least one mm-wave launcher.

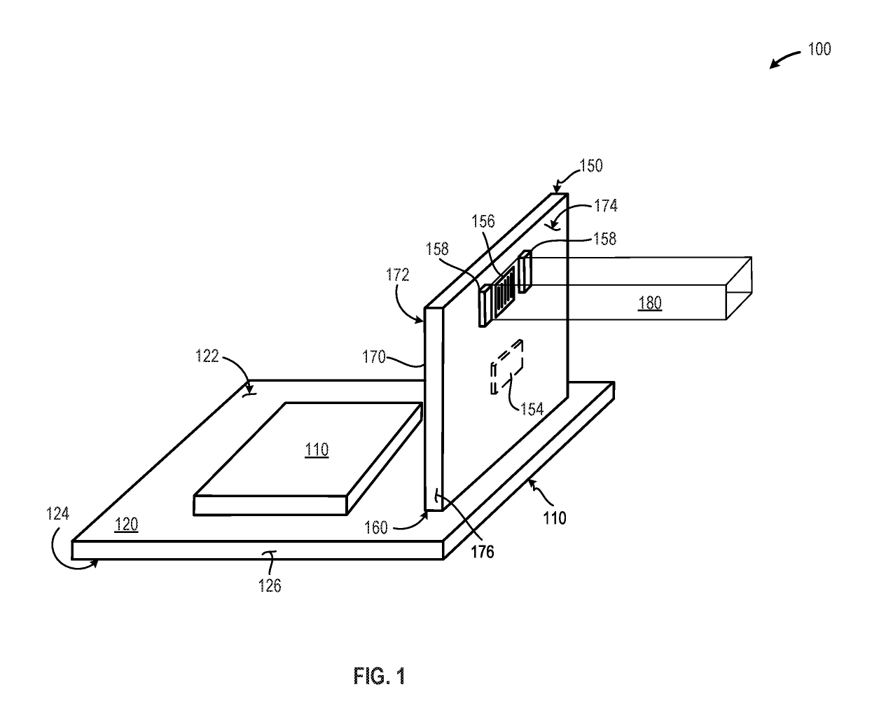

FIG. 1 provides a cross-sectional elevation of an illustrative millimeter wave (mm-wave) communication interface that includes a first subsystem 110 that includes a first semiconductor package 110 disposed on a first substrate 120 operably and communicably coupled to a second subsystem 150 that includes at least one mm-wave die 154 and at least one mm-wave launcher 156 disposed on a second substrate 170, in accordance with at least one embodiment described herein. As depicted in FIG. 1, the second substrate 170 may be operably coupled to the first substrate 120 at approximately a 90° angle. The first substrate 120 may include a generally planar member having a first surface 122 and a second surface 124. The second substrate 170 may include a generally planar member having a first surface 172 and a transversely opposed second surface 174. One or more interfaces 160 may communicably couple the second substrate 170 to the first substrate 120. In embodiments, the one or more interfaces 160 may operably couple the second substrate 170 to the first substrate 120.

In some implementations, the second subsystem 150 may include a mm-wave die 154 communicably coupled to a second semiconductor package (not illustrated in FIG. 1). The second subsystem 150 may additionally include at least one mm-wave launcher 156. Each of the mm-wave dies 154 may be communicably coupled to a respective mm-wave launcher 156. In at least some implementations, the mm-wave die 154 may be operably and/or communicably coupled to the first side 172 of the second substrate 170. In at least some implementations, the at least one mm-wave launcher 156 may be disposed proximate the second surface 174 of the second substrate 170. One or more waveguide member connection features 158 may be disposed proximate the at least one mm-wave launcher 156. In some implementations, the one or more waveguide connection features 158 may operably and/or communicably couple a waveguide member 180 proximate the mm-wave launcher 156.

The first semiconductor package 110 may include any number and/or combination of any currently available and/or future developed electronic components and/or semiconductor devices, such as one or more central processing units (CPUs) capable of providing at least one serial and/or data output. In some implementations, the first semiconductor package 110 may include one or more other components, such as one or more serializers, one or more deserializers, or one or more serializer/deserializers (SERDES). In some implementations, the one or more serializers, one or more deserializers, and/or one or more SERDES may be communicably coupled to the one or more CPUs. The SERDES may receive data from one or more sources within the first semiconductor package 110, serialize the data and provide one or more outputs capable of communicating the serialized data from the first semiconductor package 110 to the mm-wave die 154.

The first substrate 120 may include any number and/or combination of currently available and/or future developed substrates capable of carrying one or more electronic components and/or semiconductor devices. In some implementations, the first substrate 120 may include a single- or multi-layer printed circuit board, semiconductor package, interposer, embedded die, or similar structure. In some implementations the first substrate 120 may include a generally planar member having a first side 122 and a second side 124 that are bounded by a peripheral edge 126. In some implementations, the first substrate 120 may include a number of surface mount components, such as the first semiconductor package 110. In embodiments, the first substrate may additionally include one or more surface mount connectors, sockets, or similar to accommodate the physical, operational, and/or communicable coupling of the second substrate 170. In some implementations, the first substrate may include one or more edge connectors, land grid arrays (LGAs), lands, contacts, or similar interfaces to permit the physical, operational, and/or communicable coupling of the second substrate 170. In some implementations, the first substrate 120 may include one or more printed circuit boards used in a rack-mounted blade system or device, such as a blade server or similar system or device.

The second substrate 170 may include any number and/or combination of currently available and/or future developed substrates capable of carrying one or more electronic components and/or semiconductor devices. In some implementations, the second substrate 170 may include a single- or multi-layer printed circuit board, semiconductor package, interposer, embedded die, or similar structure. In some implementations the second substrate 170 may include a generally planar member having a first side 172 and a second side 174 that are bounded by a peripheral edge 176. In some implementations, the second substrate 170 may include a number of lands, plugs, connectors, sockets or similar connection features to accommodate the physical, operational, and/or communicable coupling of the second substrate 170 to the first substrate 120. In some implementations, the connection features 160 permit the physical coupling of the second substrate 170 to the first substrate 120 at an approximate right (i.e., 90°) angle such that the edge 176 of the second substrate 170 is disposed proximate the first surface 122 of the first substrate 120, such as depicted in FIG. 1.

In some implementations, the second semiconductor package 152 may be disposed on the first surface 172 of the second substrate 170. The second semiconductor package 152 may include any number and/or combination of currently available and/or future developed electronic components and/or semiconductor devices. In some implementations, the second semiconductor package 152 may include one or more mm-wave dies 154 that provide a millimeter carrier wave for the serialized data generated by the first semiconductor package 110 and provided to the second semiconductor packages 152 via the interface 160.

The one or more mm-wave dies 154 may include any number and/or combination of currently available and/or future developed devices and/or systems for modulating digital data onto a microwave frequency carrier signal. Each of the one or more mm-wave dies 154 may include a device or system capable of modulating digital data onto a carrier signal operating at a one or more frequencies of from about 30 GHz to about 300 GHz. Each of the one or more mm-wave dies 154 may transmit the high-frequency signal to a respective mm-wave launcher 156.

The mm-wave launcher 156 may include any number and/or combination of currently available and/or future developed devices and/or systems capable of receiving a high frequency signal and generating a radio frequency (RF) output representative of the received high frequency signal. In some implementations, the mm-wave launcher 156 may be disposed in, on, or about the second surface 174 of the second substrate 170. Although not depicted in FIG. 1, in some implementations, the mm-wave launcher 156 may be disposed beneath the second surface 174 of the second substrate 170 and one or more conductive structures that provide waveguide launcher structure may be disposed between the mm-wave launcher 156 and the second surface 174 of the second substrate 170. The mm-wave launcher 156 may include one or more planar members or one or more planar member arrays.

One or more waveguide member connection features 158 may be disposed proximate each of the one or more mm-wave launchers 156. The one or more waveguide member connection features 158 permit the operable and/or conductive coupling of a waveguide member 180 proximate the mm-wave launcher 156 in a location that maximizes the energy transfer, or alternatively minimizes energy losses, from the mm-wave launcher 156 to the waveguide member 180. The one or more waveguide member connection features 158 may include one or more conductive structures, such as one or more photolithographically formed conductive structures patterned onto at least a portion of the second surface 174 of the second substrate 170.

In some implementations, the one or more waveguide connection features 158 may be disposed, in whole or in part, on the second surface 176 of the second substrate 170. In some implementations, the one or more waveguide connection features 158 may be disposed in whole or in part in the second surface 176 of the second substrate 170. In some embodiments, the one or more waveguide member connection features 158 may permit the detachable attachment of the waveguide member 180 to the second substrate 170. In other embodiments, the one or more waveguide member connection features 158 permit the permanent affixation of the waveguide member 180 to the second substrate 170.

The system depicted in FIG. 1 advantageously permits the coupling of a waveguide member 180 in a defined location proximate the mm-wave launcher 156 such that the energy transfer from the mm-wave launcher 156 is maximized. Additionally, the vertical position of the second substrate 170 beneficially permits the waveguide member 180 to exit on the same plane as the blade device in which the first substrate 120 is mounted without requiring the use of performance-robbing bends or elbows within the waveguide member 180 itself. Further, the configuration depicted in FIG. 1 places all high-frequency components (e.g., the mm-wave die 154 and the mm-wave launcher 156) on the second substrate 170, thereby eliminating the use of efficiency reducing connectors in high-frequency applications. In addition, the overall height of the second substrate 170 (i.e., the distance the second substrate 170 projects above the first surface 122 of the first substrate 120) may be less than the blade spacing in a rack-mount system, and thus, the system depicted in FIG. 1 may be incorporated into existing rack designs without requiring redesign.

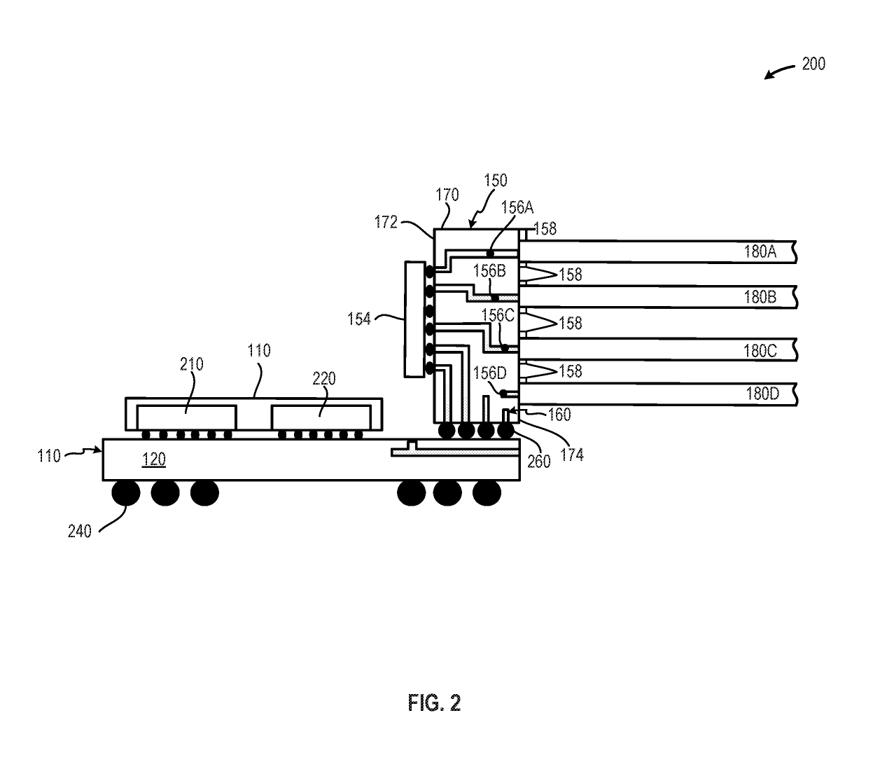

FIG. 2 provides a partial cross-sectional elevation of an illustrative mm-wave communication interface system 200 that includes a first subsystem 110 that includes a central processing unit (CPU) die 210 and a serializer/deserializer (SERDES) die 220 disposed on a first substrate 120 operably and communicably coupled to a second subsystem 150 that includes at least one mm-wave die 154 and at least one mm-wave launcher 156, in accordance with at least one embodiment described herein. As depicted in FIG. 2, in some implementations, a ball grid array 260 may provide all or a portion of the interface 160 between the second substrate 170 and the first substrate 120. Additionally, the first substrate 120 may operably and/or communicably couple to an external structure such as a blade device (e.g., a blade server) via one or more land grid arrays or ball grid arrays 240. Although the SERDES die 220 is depicted in FIG. 2 as included in the first semiconductor package 110, in some implementations the SERDES 220 may be disposed in whole or in part in the second semiconductor package 150.

The first semiconductor package 110 may include one or more CPU dies 210 and one or more SERDES dies 220. In embodiments, the one or more SERDES dies 220 may serialize at least a portion of the data provided by the one or more CPU dies 210. Additionally, the one or more SERDES dies 220 may communicate or otherwise transmit the serialized data to one or more mm-wave dies 154 via the interface 160.

As evidenced in FIG. 2, the mm-wave die 154 may operably couple to any number of mm-wave launchers 156A-156D using any combination of thru-layer vias and traces or similar conductive structures disposed in, on, or about the second substrate 170. Although not depicted in FIG. 2, in some implementations, one or more conductive structures that extend from the mm-wave launcher 156A-156D to a respective waveguide member 180A-180D, for example one or more horn waveguide launcher structures, may be partially or completely disposed in the second substrate 170.

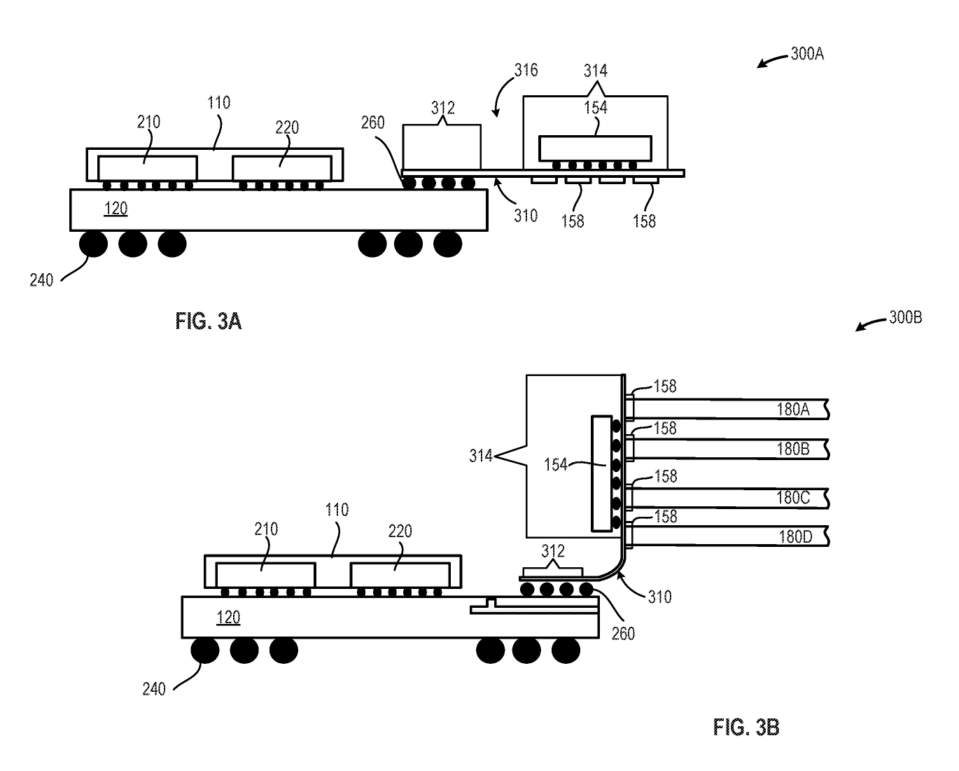

FIG. 3A provides a partial cross-sectional elevation of an illustrative mm-wave communication interface system 300A that includes a first subsystem 110 that includes a first substrate 120 operably and communicably coupled to a flexible substrate 310 disposed in a first position that includes at least one mm-wave die 154 and at least one mm-wave launcher, in accordance with at least one embodiment described herein. FIG. 3B provides a partial cross-sectional elevation of an illustrative mm-wave communication interface system 300B in which the flexible second substrate 310 has been displaced or rotated to a configuration in which at least a portion of the second substrate 310 extends normal to the first surface 122 of the first substrate 120, in accordance with at least one embodiment described herein.

As depicted in FIG. 3, in at least some implementations, all or a portion of the second substrate may include one or more flexible second substrates 310. In embodiments, the flexible second substrate 310 may include a rigid first portion 312 and a rigid second portion 314 physically coupled via a flexible substrate portion 316. In such an embodiment, the rigid first portion 312 of the flexible second substrate 310 may be operably coupled to the first substrate 120, for example via one or more ball grid arrays 260 as depicted in FIGS. 3A and 3B. Similarly, the one or more mm-wave dies 174 may be operably and/or communicably coupled to the rigid second portion 314 of the second substrate 310. After assembly, the rigid second portion 314 of the flexible second substrate 310 may be rotated or otherwise displaced through an angle with respect to the rigid first portion 312 of the flexible second substrate 310. In some implementations, the rigid second portion 314 of the flexible second substrate 310 may be rotated or otherwise displaced through an angle of about 90 degrees with respect to the rigid first portion 312 of the flexible second substrate 310.

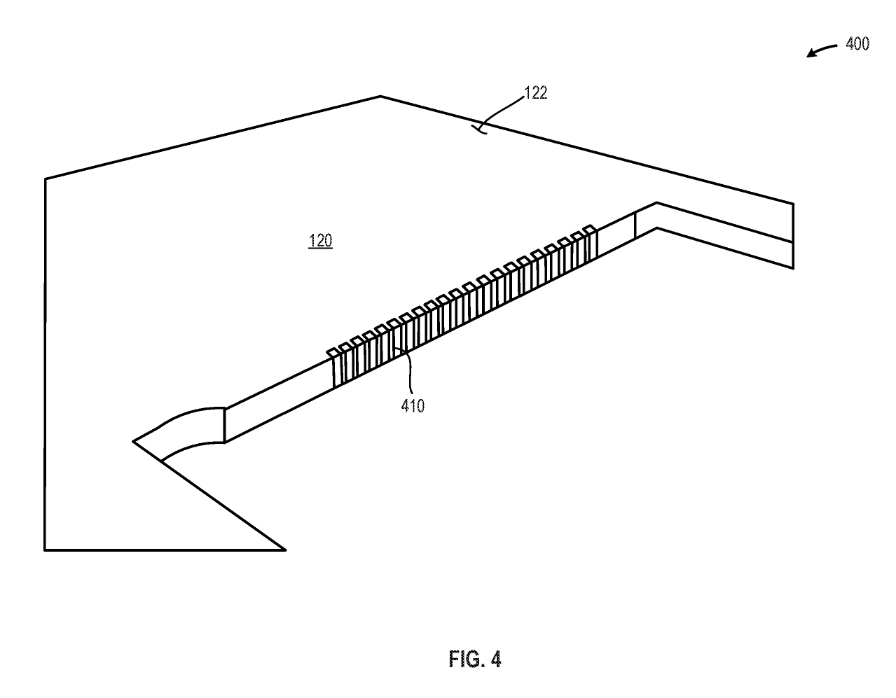

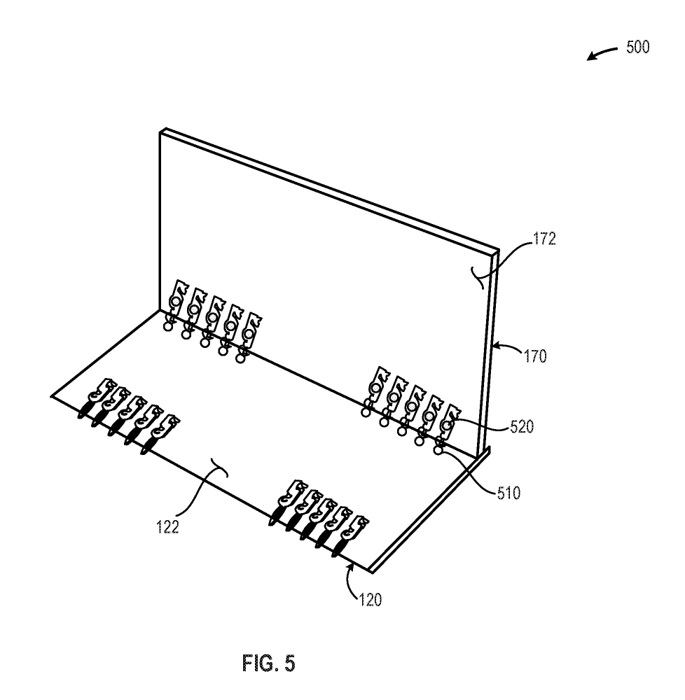

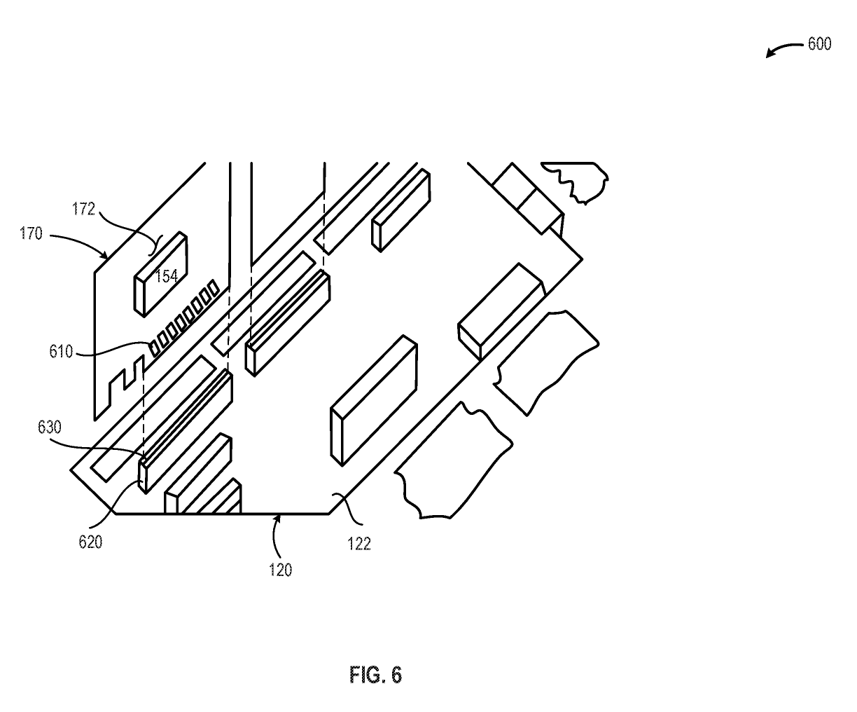

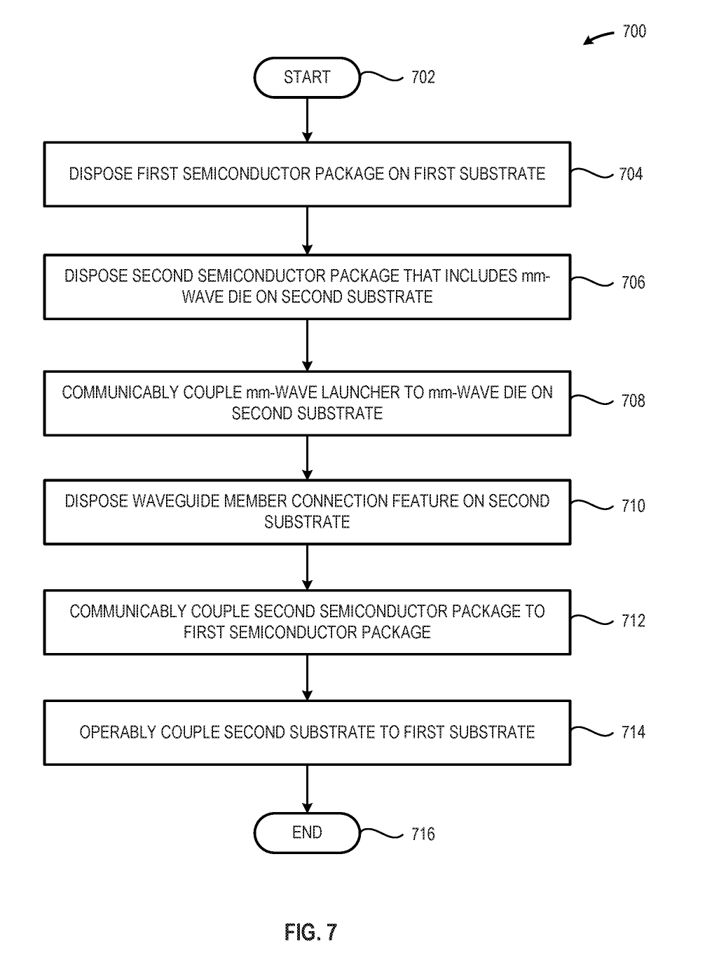

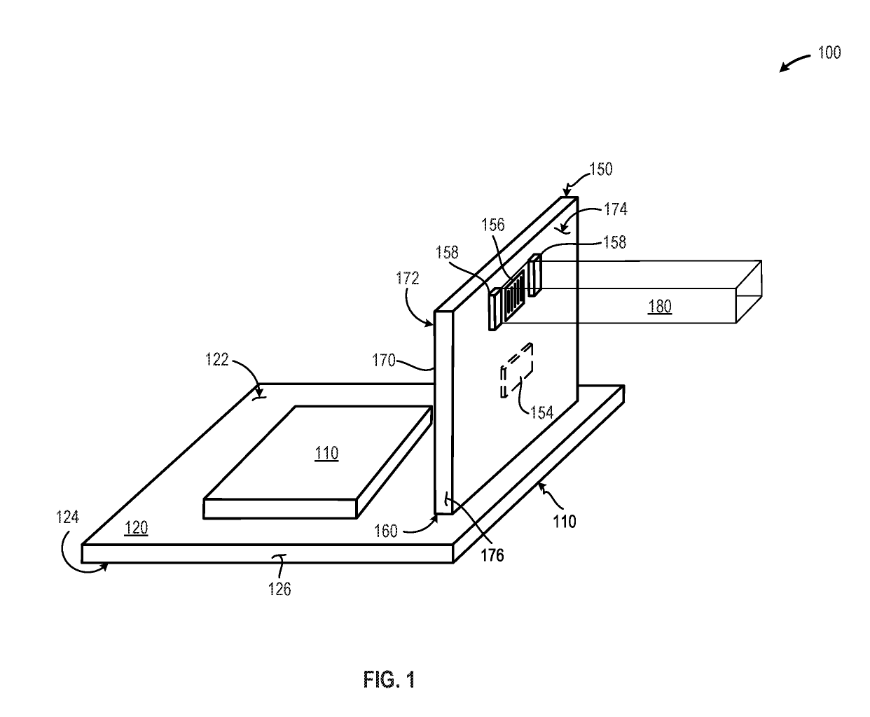

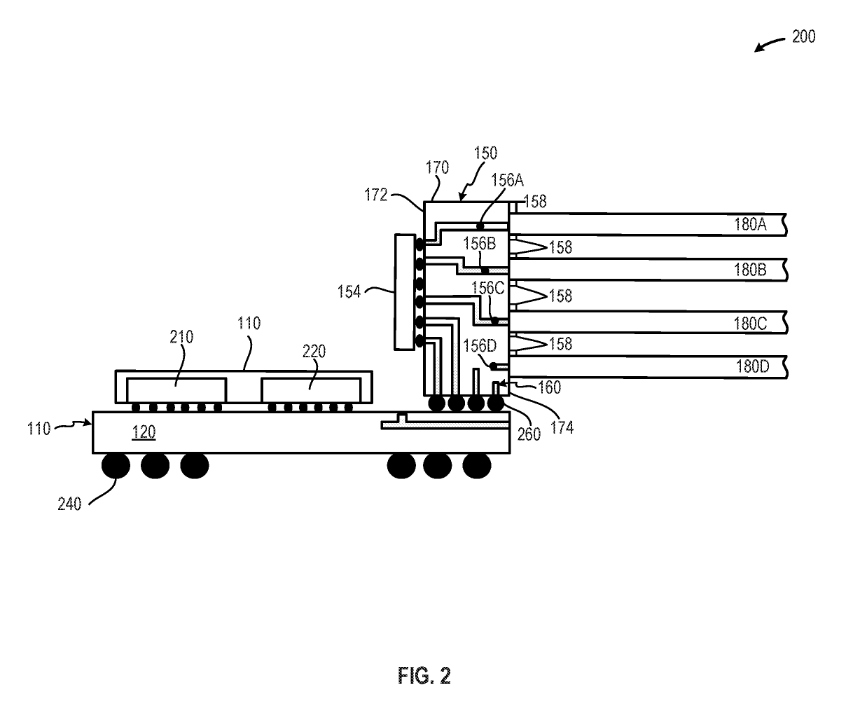

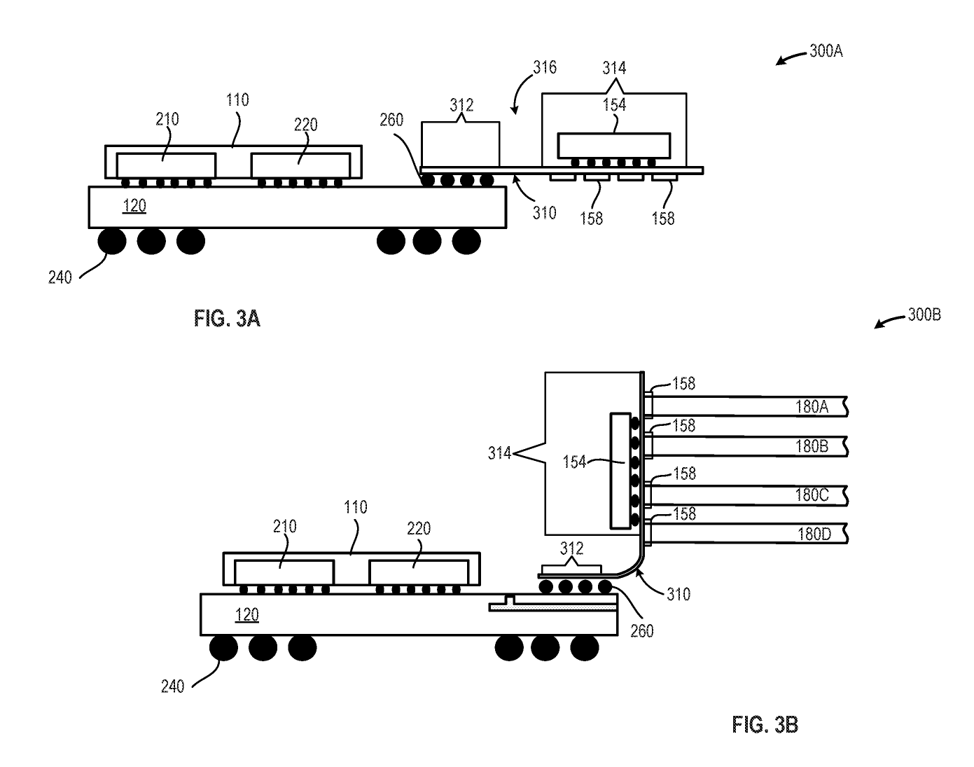

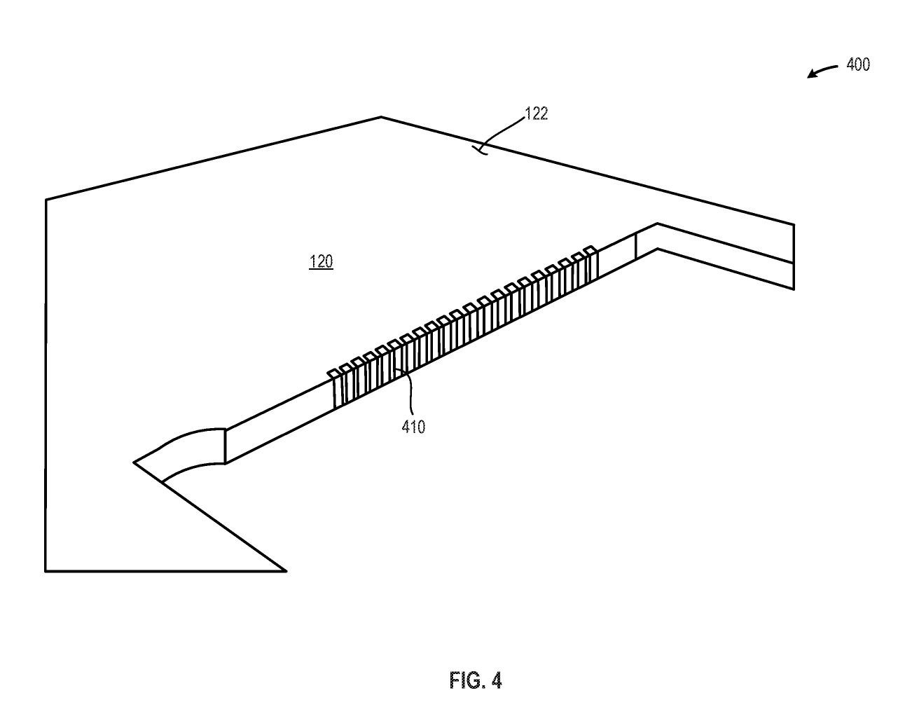

FIG. 4 provides a perspective view of an illustrative mm-wave communication interface system 400 that includes an example first substrate 120 incorporating an edge connector 410 suitable for physically, operably, and conductively coupling a second substrate 170 to the first substrate 120, in accordance with at least one embodiment described herein. The systems and methods described herein advantageously permit the coupling of a waveguide member 180 to a mm-wave launcher 156 by positioning the mm-wave launcher 156 and the waveguide member connector feature 158 on a second substrate 170 disposed at approximately 90 degrees measured with respect to the first surface 122 of the first substrate 120. The use of an edge connector 410 such as depicted in FIG. 4 may facilitate the physical, operable, and communicable coupling of the second substrate 170 to the first substrate 120.

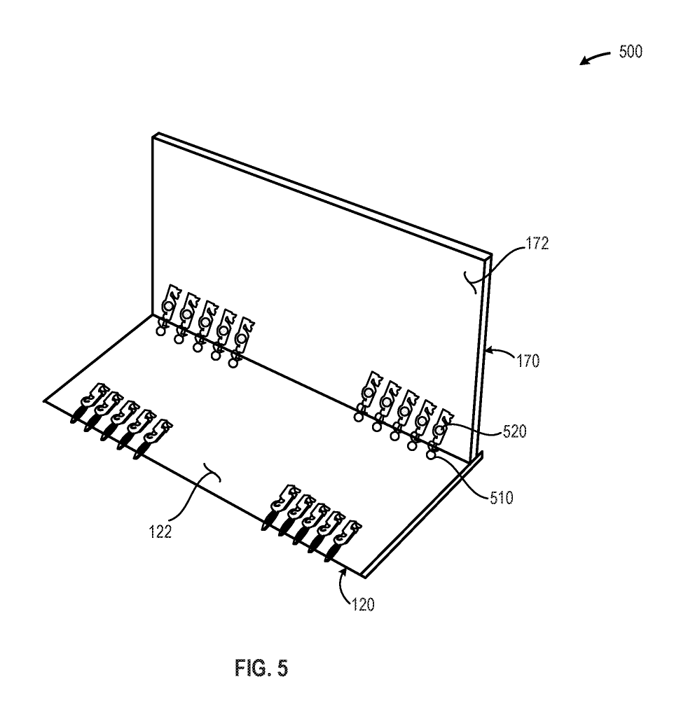

FIG. 5 provides a perspective view of an illustrative mm-wave communication interface system 500 that includes an example first substrate 120 incorporating a plurality of sockets 510 and a second substrate 170 incorporating a corresponding plurality of pins 520 insertable into to the plurality of sockets 510 to provide a “press-fit” coupling between the first substrate 120 and the second substrate 170, in accordance with at least one embodiment described herein. Inserting the plurality of pins 520 physically, operably, and communicably coupled to the second substrate 170 into the plurality of sockets 510 physically, operably, and communicably coupled to the first substrate 120 couples the second substrate 170 at an angle of about 90 degrees measured with respect to the first surface 122 of the first substrate 120.

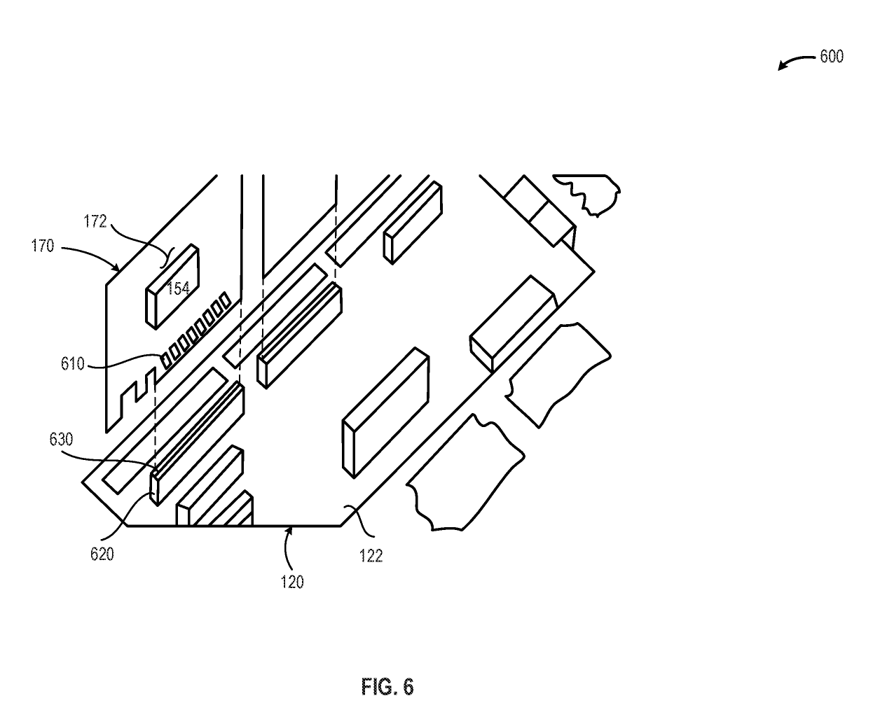

FIG. 6 provides a perspective view of an illustrative mm-wave communication interface system 600 that includes an example first substrate 120 incorporating a plurality of lands 610 and a second substrate 170 that includes a socket 620 having a corresponding plurality of contacts 630 to provide a physical, operable, and communicable coupling between the first substrate 120 and the second substrate 170, in accordance with at least one embodiment described herein. Inserting the plurality of lands 610 that are physically, operably, and communicably coupled to the second substrate 170 into the socket 620 that is physically, operably, and communicably coupled to the first substrate 120 couples the second substrate 170 at an angle of about 90 degrees measured with respect to the first surface 122 of the first substrate 120.

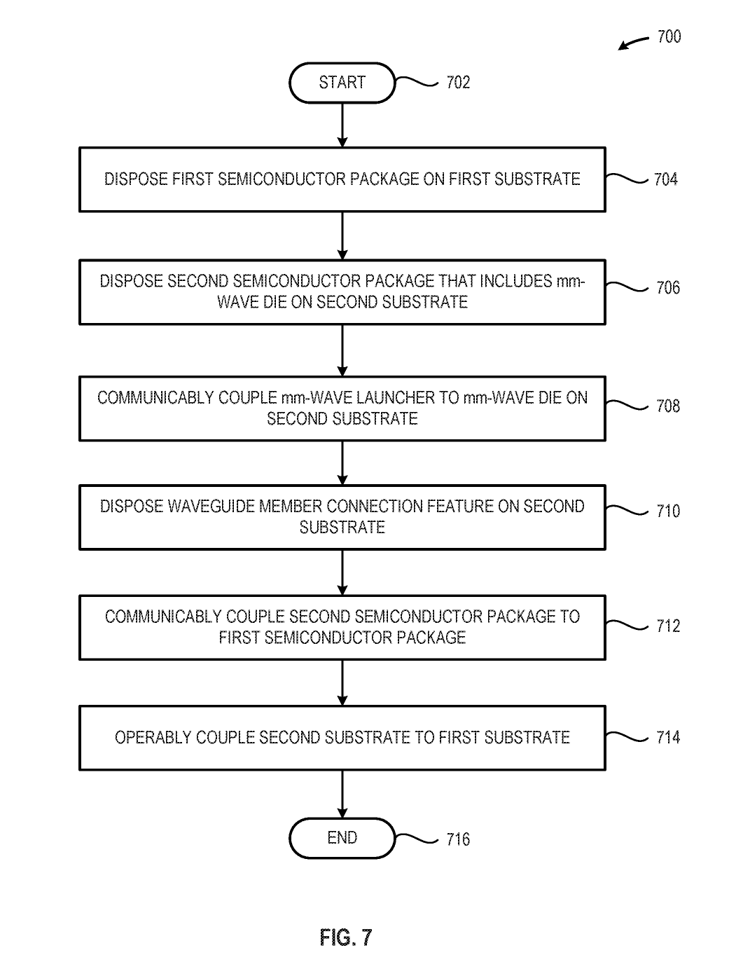

FIG. 7 provides a high-level flow diagram of an illustrative mm-wave communication interface method 700, in accordance with at least one embodiment described herein. The second substrate 170 may be physically, operably, and communicably coupled to the first substrate 120 via one or more interfaces 160. The second substrate 170 may be coupled to the first substrate 120 at about a 90° angle measured with respect to a first surface 122 of the first substrate 120. One or more waveguide members 180 may operably and/or communicably couple to the second substrate 170 such that the principal plane of the first substrate 120 is parallel to the longitudinal axis of the waveguide member 180. Thus, if a rack-mount blade device, such as a blade server, incorporates the first substrate 120, the waveguide member 180 is beneficially able to exit the rack without requiring the use of bends, curves, or other fittings that degrade the performance of the waveguide member 180. The method 700 commences at 702.

At 704, a first semiconductor package 110 may be disposed in, on, or about a first substrate 120. The first substrate 120 may include a generally planar member defined by two orthogonal axes and having a first surface 122, a transversely opposed second surface 124, bounded by a peripheral edge 126. In some implementations, the first semiconductor package 110 may include one or more central processing units (CPUs) 210. In some implementations, the first package 110 may include one or more serializer/deserializers (SERDES) 220 that may receive digital data generated or otherwise sourced from the one or more CPUs 210. In some implementations, the one or more CPUs 210 and the one or more SERDES 220 may be disposed on the first side 122 of the first substrate 120.

At 706, a second semiconductor package 152 may be disposed in, on, or, about a second substrate 170. The second substrate 170 may include a generally planar member defined by two orthogonal axes and having a first surface 172, a transversely opposed second surface 174, bounded by a peripheral edge 176. In some implementations, the second semiconductor package 152 may include one or more mm-wave dies 154 and may be physically, operationally, and/or conductively coupled to the first surface 172 of the second substrate 170. In some implementations, the one or more mm-wave dies 154 may receive the serialized data from the SERDES 220 and may module the serialized data onto a high frequency microwave carrier signal.

At 708, at least one mm-wave launcher 156 may be disposed in, on, or about the second surface 174 of the second substrate 170. In some implementations, each of the one or more mm-wave dies 154 may be communicably coupled to a respective one of at least one of the one or more mm-wave launchers 156. In such implementations, the one or more mm-wave launchers 156 may receive the modulated microwave signal from the respective mm-wave die 154.

At 710, a number of waveguide member connection features may be disposed in, on, or about the second surface 174 of the second substrate 170. In some implementations, the number of waveguide member connection features 158 may be disposed proximate the one or more mm-wave launchers 156. Advantageously, disposal of the waveguide member connection features 158 proximate the one or more mm-wave launchers 156 beneficially permits the alignment of a waveguide member 180 engaged with the waveguide member connection features 158 with the respective mm-wave launcher 156 such that the energy transferred from the mm-wave launcher 156 to the waveguide member 180 is maximized.

At 712, the second semiconductor package 152 may be communicably coupled to the first semiconductor package 110. The second semiconductor package 152 may be communicably coupled to the first semiconductor package 110 via the one or more interfaces 160. As discussed above, such communicable coupling may be achieved using one or more soldered connections (e.g., via edge contacts), one or more press-fit connections, or one or more socket connections. In some implementations, the CPU 210 carried by the first semiconductor package 110 may be communicably coupled to a SERDES 220 carried by the second semiconductor package 152. In some implementations, the SERDES 220 carried by the first semiconductor package 110 may be communicably coupled to a mm-wave die 154 carried by the second semiconductor package 152. Advantageously, all high frequency components are carried by the second semiconductor package 152, thus all high frequency communications are provided via high reliability traces and/or connections.

At 714, the second semiconductor substrate 170 is physically and/or operably coupled to the first semiconductor substrate 120. In embodiments, the planar second semiconductor substrate 170 may be physically and/or operably coupled to the planar first semiconductor substrate 120 such that an angle of approximately 90° is formed between the first surface 122 of the first semiconductor substrate 120 and the second semiconductor substrate 170. The method 700 concludes at 716.

Additionally, operations for the embodiments have been further described with reference to the above figures and accompanying examples. Some of the figures may include a logic flow. Although such figures presented herein may include a particular logic flow, it can be appreciated that the logic flow merely provides an example of how the general functionality described herein can be implemented. Further, the given logic flow does not necessarily have to be executed in the order presented unless otherwise indicated. The embodiments are not limited to this context.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications. Thus, the breadth and scope of the present invention should not be limited by any of the above-described exemplary embodiments, but should be defined only in accordance with the following claims and their equivalents.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

According to example 1, there is provided a semiconductor package waveguide coupling system. The system may include: a first semiconductor package disposed on a first substrate that includes a first surface and a transversely opposed second surface; and a second semiconductor package disposed on a second substrate that includes a first surface and a transversely opposed second surface. The second semiconductor package may be communicably coupled to the first semiconductor package; and the second substrate may be operably coupled to the first substrate. The second semiconductor package may include: at least one mm-wave die communicably coupled to the second substrate; at least one mm-wave launcher communicably coupled to the mm-wave die; and at least one waveguide member connection feature to accommodate the operable and conductive coupling of a waveguide member to the second semiconductor package proximate the at least one mm-wave launcher.

Example 2 may include elements of example 1 where the second substrate may operably couple at approximately a right angle to the first surface of the first substrate.

Example 3 may include elements of example 1 where the operably and conductively coupled waveguide member may extend from the first surface of the second substrate at approximately a right angle to the first surface of the second substrate.

Example 4 may include elements of example 3 where the at least one mm-wave die may be operably and communicably coupled to the second surface of the second substrate.

Example 5 may include elements of example 4 where the at least one mm-wave launcher may be disposed proximate the first surface of the second substrate.

Example 6 may include elements of example 1 where the second substrate may further include a semiconductor package integrated horn waveguide launcher disposed at least partially between each of the at least one mm-wave launchers and a respective one of the at least one waveguide member connection features.

Example 7 may include elements of example 1 where the first semiconductor package comprises at least one central processing unit (CPU) die and at least one serializer/deserializer (SERDES).

Example 8 may include elements of example 1 where the first semiconductor package may include at least one central processing unit (CPU) die; and where the second semiconductor package further comprises at least one serializer/deserializer (SERDES) communicably coupled to the at least one mm-wave die.

Example 9 may include elements of example 1 where the first semiconductor package may include a ball grid array (BGA) semiconductor package.

Example 10 may include elements of example 1 where the first semiconductor package may include a land grid array (LGA) semiconductor package.

Example 11 may include elements of any of examples 1 through 10 where the first substrate may further include an edge plated connector; and where a solder connection between the second semiconductor package and the edge plated connector may provide the operable coupling between the second substrate and the first substrate and the communicable coupling between the second semiconductor package and the first semiconductor package.

Example 12 may include elements of any of examples 1 through 10 where the first substrate may further include a surface mount edge connector disposed on the first side of the first substrate; and where the second semiconductor package may include an array of electrical contacts complimentary to the surface mount edge connector, and the surface mount edge connector provides the operable coupling between the second substrate and the first substrate and the communicable coupling between the second semiconductor package and the first semiconductor package.

According to example 13, there is provided a semiconductor package waveguide coupling method. The method may include disposing a first semiconductor package on a first substrate that includes a first surface and a transversely opposed second surface; disposing a second semiconductor package including at least one communicably coupled mm-wave die on a second substrate, the second substrate including a first surface and a transversely opposed second surface; disposing at least one mm-wave launcher on the second substrate, the at least one mm-wave launcher communicably coupled to the mm-wave die; disposing at least one waveguide member connection feature on the second substrate, the at least one waveguide member connection feature to accommodate the operable and conductive coupling of a waveguide member to the second semiconductor package proximate the at least one mm-wave launcher; communicably coupling the first semiconductor package to the second semiconductor package; and operably coupling the second substrate to the first substrate.

Example 14 may include elements of example 13 where operably coupling the second substrate to the first substrate may include: operably coupling the second substrate to the first surface of the first substrate at approximately a right angle measured with respect to the first surface of the first substrate.

Example 15 may include elements of example 13, and may additionally include operably and conductively coupling a waveguide member to the at least one waveguide member connection feature.

Example 16 may include elements of example 15 where operably and conductively coupling a waveguide member the at least one waveguide member connection feature may include: operably coupling the waveguide member to the at least one waveguide member connection feature such that the operably coupled waveguide member extends from the first surface of the second substrate at approximately a right angle to the first surface of the second substrate.

Example 17 may include elements of example 13 where disposing a second semiconductor package including at least one communicably coupled mm-wave die on a second substrate, may include: disposing the second semiconductor package on the second surface of the at second semiconductor package.

Example 18 may include elements of example 17 where disposing at least one mm-wave launcher on the second substrate may include: disposing at least one mm-wave launcher proximate the first surface of the second substrate.

Example 19 may include elements of example 13, and may additionally include: disposing a semiconductor package integrated horn waveguide launcher disposed at least partially between each of the at least one mm-wave launchers and a respective one of the at least one waveguide member connection features.

Example 20 may include elements of example 13 where disposing a first semiconductor package on a first substrate may include: disposing a first semiconductor package that includes at least one central processing unit (CPU) die and at least one serializer/deserializer (SERDES) on the first substrate.

Example 21 may include elements of example 13 where disposing a first semiconductor package on a first substrate may include: disposing a first semiconductor package that includes at least one central processing unit (CPU) die on the first substrate; and where disposing a second semiconductor package including at least one communicably coupled mm-wave die on a second substrate may include: disposing a second semiconductor package that includes at least one communicably coupled mm-wave die and at least one communicably coupled serializer/deserializer (SERDES) on the second substrate.

Example 22 may include elements of example 13 where disposing a first semiconductor package on a first substrate may include: disposing a first semiconductor package that includes a ball grid array (BGA) semiconductor package on the first substrate.

Example 23 may include elements of example 13 where disposing a first semiconductor package on a first substrate may include: disposing a first semiconductor package that includes a land grid array (LGA) semiconductor package on the first substrate.

Example 24 may include elements of any of examples 13 through 23 where disposing a first semiconductor package on a first substrate may include: disposing a first semiconductor package on a first substrate that further includes an edge plated connector; and where communicably coupling the first semiconductor package to the second semiconductor package may include: forming a solder connection between the second semiconductor package and the edge plated connector to provide the operable coupling between the second substrate and the first substrate and the communicable coupling between the second semiconductor package and the first semiconductor package.

Example 25 may include elements of any of examples 13 through 23 where disposing a first semiconductor package on a first substrate may include: disposing a first semiconductor package on a first substrate that further includes a surface mount edge connector disposed on the first side of the first substrate; and where communicably coupling the first semiconductor package to the second semiconductor package may include: engaging an array of electrical contacts disposed on the second substrate and complimentary to the surface mount edge connector with the surface mount edge connector to provide the operable coupling between the second substrate and the first substrate and the communicable coupling between the second semiconductor package and the first semiconductor package.

According to example 26, there is provided a semiconductor package waveguide coupling system. The system may include: a means for disposing a first semiconductor package on a first substrate that includes a first surface and a transversely opposed second surface; a means for disposing a second semiconductor package including at least one communicably coupled mm-wave die on a second substrate, the second substrate including a first surface and a transversely opposed second surface; a means for disposing at least one mm-wave launcher on the second substrate, the at least one mm-wave launcher communicably coupled to the mm-wave die; a means for disposing at least one waveguide member connection feature on the second substrate, the at least one waveguide member connection feature to accommodate the operable and conductive coupling of a waveguide member to the second semiconductor package proximate the at least one mm-wave launcher; a means for communicably coupling the first semiconductor package to the second semiconductor package; and a means for operably coupling the second substrate to the first substrate.

Example 27 may include elements of example 26 where the means for operably coupling the second substrate to the first substrate may include: a means for operably coupling the second substrate to the first surface of the first substrate at approximately a right angle measured with respect to the first surface of the first substrate.

Example 28 may include elements of example 26, and may additionally include a means for operably and conductively coupling a waveguide member to the at least one waveguide member connection feature.

Example 29 may include elements of example 28 where the means for operably and conductively coupling a waveguide member the at least one waveguide member connection feature may include: a means for operably coupling the waveguide member to the at least one waveguide member connection feature such that the operably coupled waveguide member extends from the first surface of the second substrate at approximately a right angle to the first surface of the second substrate.

Example 30 may include elements of example 26 where the means for disposing a second semiconductor package including at least one communicably coupled mm-wave die on a second substrate may include a means for disposing the second semiconductor package on the second surface of the at second semiconductor package.

Example 31 may include elements of example 30 where the means for disposing at least one mm-wave launcher on the second substrate may include a means for disposing at least one mm-wave launcher proximate the first surface of the second substrate.

Example 32 may include elements of example 26, and may additionally include a means for disposing a semiconductor package integrated horn waveguide launcher disposed at least partially between each of the at least one mm-wave launchers and a respective one of the at least one waveguide member connection features.

Example 33 may include elements of example 26 where disposing a first semiconductor package on a first substrate may include a means for disposing a first semiconductor package that includes at least one central processing unit (CPU) die and at least one serializer/deserializer (SERDES) on the first substrate.

Example 34 may include elements of example 26 where the means for disposing a first semiconductor package on a first substrate may include a means for disposing a first semiconductor package that includes at least one central processing unit (CPU) die on the first substrate; and where the means for disposing a second semiconductor package including at least one communicably coupled mm-wave die on a second substrate may include a means for disposing a second semiconductor package that includes at least one communicably coupled mm-wave die and at least one communicably coupled serializer/deserializer (SERDES) on the second substrate.

Example 35 may include elements of example 26 where the means for disposing a first semiconductor package on a first substrate may include a means for disposing a first semiconductor package that includes a ball grid array (BGA) semiconductor package on the first substrate.

Example 36 may include elements of example 26 where the means for disposing a first semiconductor package on a first substrate may include a means for disposing a first semiconductor package that includes a land grid array (LGA) semiconductor package on the first substrate.

Example 37 may include elements of any of examples 26 through 36 where the means for disposing a first semiconductor package on a first substrate may include a means for disposing a first semiconductor package on a first substrate that further includes an edge plated connector; and where the means for communicably coupling the first semiconductor package to the second semiconductor package may include a means for forming a solder connection between the second semiconductor package and the edge plated connector to provide the operable coupling between the second substrate and the first substrate and the communicable coupling between the second semiconductor package and the first semiconductor package.

Example 38 may include elements of any of examples 26 through 36 where the means for disposing a first semiconductor package on a first substrate may include a means for disposing a first semiconductor package on a first substrate that further includes a surface mount edge connector disposed on the first side of the first substrate; and where the means for communicably coupling the first semiconductor package to the second semiconductor package comprises a means for engaging an array of electrical contacts disposed on the second substrate and complimentary to the surface mount edge connector with the surface mount edge connector to provide the operable coupling between the second substrate and the first substrate and the communicable coupling between the second semiconductor package and the first semiconductor package.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1. A semiconductor package waveguide coupling system, comprising:
a first semiconductor package disposed on a first substrate that includes a first surface and a transversely opposed second surface; and
a second semiconductor package disposed on a second substrate that includes a first surface and a transversely opposed second surface;
the second semiconductor package communicably coupled to the first semiconductor package; and
the second substrate operably coupled to the first substrate;
wherein the second semiconductor package includes:
at least one mm-wave die communicably coupled to the second substrate
at least one mm-wave launcher communicably coupled to the mm-wave die; and
at least one waveguide member connection feature to accommodate the operable and conductive coupling of a waveguide member to the second semiconductor package proximate the at least one mm-wave launcher.

2. The system of claim 1 wherein the second substrate operably couples at approximately a right angle to the first surface of the first substrate.

3. The system of claim 1 wherein the operably and conductively coupled waveguide member extends from the first surface of the second substrate at approximately a right angle to the first surface of the second substrate.

4. The system of claim 3 wherein the at least one mm-wave die is operably and communicably coupled to the second surface of the second substrate.

5. The system of claim 4 wherein the at least one mm-wave launcher is disposed proximate the first surface of the second substrate.

6. The system of claim 1 wherein the second substrate further includes a semiconductor package integrated horn antenna disposed at least partially between each of the at least one mm-wave launchers and a respective one of the at least one waveguide member connection features.

7. The system of claim 1 wherein the first semiconductor package comprises at least one central processing unit (CPU) die and at least one serializer/deserializer (SERDES).

8. The system of claim 1:
wherein the first semiconductor package comprises at least one central processing unit (CPU) die; and
wherein the second semiconductor package further comprises at least one serializer/deserializer (SERDES) communicably coupled to the at least one mm-wave die.

9. The system of claim 1 wherein the first semiconductor package comprises a ball grid array (BGA) semiconductor package.

10. The system of claim 1 wherein the first semiconductor package comprises a land grid array (LGA) semiconductor package.

11. The system of claim 1:
wherein the first substrate further includes an edge plated connector; and
wherein a solder connection between the second semiconductor package and the edge plated connector provides the operable coupling between the second substrate and the first substrate and the communicable coupling between the second semiconductor package and the first semiconductor package.

12. The system of claim 1:
wherein the first substrate further includes a surface mount edge connector disposed on the first side of the first substrate; and
wherein the second semiconductor package includes an array of electrical contacts complimentary to the surface mount edge connector, and the surface mount edge connector provides the operable coupling between the second substrate and the first substrate and the communicable coupling between the second semiconductor package and the first semiconductor package.

13. A semiconductor package waveguide coupling method, comprising:
disposing a first semiconductor package on a first substrate that includes a first surface and a transversely opposed second surface; and
disposing a second semiconductor package including at least one communicably coupled mm-wave die on a second substrate, the second substrate including a first surface and a transversely opposed second surface;
disposing at least one mm-wave launcher on the second substrate, the at least one mm-wave launcher communicably coupled to the mm-wave die;
disposing at least one waveguide member connection feature on the second substrate, the at least one waveguide member connection feature to accommodate the operable and conductive coupling of a waveguide member to the second semiconductor package proximate the at least one mm-wave launcher;
communicably coupling the first semiconductor package to the second semiconductor package; and
operably coupling the second substrate to the first substrate.

14. The method of claim 13 wherein operably coupling the second substrate to the first substrate comprises:
operably coupling the second substrate to the first surface of the first substrate at approximately a right angle measured with respect to the first surface of the first substrate.

15. The method of claim 13, further comprising:
operably and conductively coupling a waveguide member to the at least one waveguide member connection feature.

16. The method of claim 15 wherein operably and conductively coupling a waveguide member the at least one waveguide member connection feature comprises:
operably coupling the waveguide member to the at least one waveguide member connection feature such that the operably coupled waveguide member extends from the first surface of the second substrate at approximately a right angle to the first surface of the second substrate.

17. The method of claim 13 wherein disposing a second semiconductor package including at least one communicably coupled mm-wave die on a second substrate, comprises:
disposing the second semiconductor package on the second surface of the at second semiconductor package.

18. The method of claim 17 wherein disposing at least one mm-wave launcher on the second substrate comprises:
disposing at least one mm-wave launcher proximate the first surface of the second substrate.

19. The method of claim 13, further comprising:
disposing a semiconductor package integrated horn antenna disposed at least partially between each of the at least one mm-wave launchers and a respective one of the at least one waveguide member connection features.

20. The method of claim 13 wherein disposing a first semiconductor package on a first substrate comprises:
disposing a first semiconductor package that includes at least one central processing unit (CPU) die and at least one serializer/deserializer (SERDES) on the first substrate.

21. The method of claim 13:
wherein disposing a first semiconductor package on a first substrate comprises:
disposing a first semiconductor package that includes at least one central processing unit (CPU) die on the first substrate; and
wherein disposing a second semiconductor package including at least one communicably coupled mm-wave die on a second substrate comprises:
disposing a second semiconductor package that includes at least one communicably coupled mm-wave die and at least one communicably coupled serializer/deserializer (SERDES) on the second substrate.

22. The method of claim 13 wherein disposing a first semiconductor package on a first substrate comprises:
disposing a first semiconductor package that includes a ball grid array (BGA) semiconductor package on the first substrate.

23. The method of claim 13 wherein disposing a first semiconductor package on a first substrate comprises:
disposing a first semiconductor package that includes a land grid array (LGA) semiconductor package on the first substrate.

24. The method of claim 13:
wherein disposing a first semiconductor package on a first substrate comprises:
disposing a first semiconductor package on a first substrate that further includes an edge plated connector; and
wherein communicably coupling the first semiconductor package to the second semiconductor package comprises:
forming a solder connection between the second semiconductor package and the edge plated connector to provide the operable coupling between the second substrate and the first substrate and the communicable coupling between the second semiconductor package and the first semiconductor package.

25. The method of claim 13:
wherein disposing a first semiconductor package on a first substrate comprises:
disposing a first semiconductor package on a first substrate that further includes a surface mount edge connector disposed on the first side of the first substrate; and
wherein communicably coupling the first semiconductor package to the second semiconductor package comprises:
engaging an array of electrical contacts disposed on the second substrate and complimentary to the surface mount edge connector with the surface mount edge connector to provide the operable coupling between the second substrate and the first substrate and the communicable coupling between the second semiconductor package and the first semiconductor package.

26. A semiconductor package waveguide coupling system, comprising:
a means for disposing a first semiconductor package on a first substrate that includes a first surface and a transversely opposed second surface; and
a means for disposing a second semiconductor package including at least one communicably coupled mm-wave die on a second substrate, the second substrate including a first surface and a transversely opposed second surface;
a means for disposing at least one mm-wave launcher on the second substrate, the at least one mm-wave launcher communicably coupled to the mm-wave die;
a means for disposing at least one waveguide member connection feature on the second substrate, the at least one waveguide member connection feature to accommodate the operable and conductive coupling of a waveguide member to the second semiconductor package proximate the at least one mm-wave launcher;
a means for communicably coupling the first semiconductor package to the second semiconductor package; and
a means for operably coupling the second substrate to the first substrate.
